(19) United States
(12) Patent Application Publication
(10) Pub. No.: US 2016/0190319 A1
(43) Pub. Date: Jun. 30, 2016

(54) Non-Planar Semiconductor Devices having Multi-Layered Compliant Substrates

(71) Applicant: INTEL CORPORATION, Santa Clara, CA (US)

(72) Inventors: JACK T. KAVALIEROS, Portland, OR (US); MARKO RADOSAVLJEVIC, Beaverton, OR (US); MATTHEW V. METZ, Portland, OR (US); HAN WUI THEN, Portland, OR (US); BENJAMIN CHU-KUNG, Hillsboro, OR (US); VAN H. LE, Beaverton, OR (US); NILOY MUKHERJEE, Beaverton, OR (US); SANSAPTAK DASGUPTA, Hillsboro, OR (US); RAVI PILLARISETTY, Portland, OR (US); GILBERT DEWEY, Hillsboro, OR (US); ROBERT S. CHAU, Portland, OR (US); NANCY M. ZELICK, Portland, OR (US); WILLY RACHMADY, Beaverton, OR (US)

(21) Appl. No.: 14/912,059

(22) PCT Filed: Sep. 27, 2013
(86) PCT No.: PCT/US2013/062445

§ 371 Date: Feb. 12, 2016

(51) Int. Cl. H01L 29/78; H01L 29/165; H01L 29/66; H01L 29/267; H01L 29/06; H01L 29/161; H01L 29/20

(52) U.S. Cl. CPC H01L 29/7848; H01L 29/161; H01L 29/165; H01L 29/20; H01L 29/267; H01L 29/0653; H01L 29/66636; H01L 29/66795; H01L 29/7851

(57) ABSTRACT

Non-planar semiconductor devices having multi-layered compliant substrates and methods of fabricating such non-planar semiconductor devices are described. For example, a semiconductor device includes a semiconductor fin disposed above a semiconductor substrate. The semiconductor fin has a lower portion composed of a first semiconductor material with a first lattice constant (L1), and has an upper portion composed of a second semiconductor material with a second lattice constant (L2). A cladding layer is disposed on the upper portion, but not on the lower portion, of the semiconductor fin. The cladding layer is composed of a third semiconductor material with a third lattice constant (L3), wherein L3>L2>L1. A gate stack is disposed on a channel region of the cladding layer. Source/drain regions are disposed on either side of the channel region.

### TECHNICAL FIELD

Embodiments of the invention are in the field of semiconductor devices and processing and, in particular, non-planar semiconductor devices having multi-layered compliant substrates and methods of fabricating such non-planar semiconductor devices.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for ever-more capacity, however, is not without issue. The necessity to optimize the performance of each device becomes increasingly significant.

In the manufacture of integrated circuit devices, multi-gate transistors, such as fin field effect transistors (fin-FETs), have become more prevalent as device dimensions continue to scale down. In conventional processes, fin-FETs are generally fabricated on either bulk silicon substrates or silicon-on-insulator substrates. In some instances, bulk silicon substrates are preferred due to their lower cost and compatibility with the existing high-yielding bulk silicon substrate infrastructure.

Scaling multi-gate transistors has not been without consequence, however. As the dimensions of these fundamental building blocks of microelectronic circuitry are reduced and as the sheer number of fundamental building blocks fabricated in a given region is increased, the constraints on the semiconductor processes used to fabricate these building blocks have become overwhelming.

### BRIEF DESCRIPTION OF THE DRAWINGS

FIG. 1 illustrates a silicon fin having a cladding layer formed thereon to provide a single layer compliant substrate.

FIG. 2 illustrates a silicon fin having a cladding layer formed thereon to provide a dual layer compliant substrate, in accordance with an embodiment of the present invention.

FIGS. 3A-3E illustrate cross-sectional views of various operations in a method of fabricating a dual layer compliant substrate for a non-planar device, in accordance with an embodiment of the present invention, where:

FIG. 3A illustrates a cross-sectional view depicting a semiconductor blanket stack having a second semiconductor layer disposed on a first semiconductor layer;

FIG. 3B illustrates a cross-sectional view depicting a plurality of fins as formed from the structure of FIG. 3A;

FIG. 3C illustrates a cross-sectional view depicting isolation regions formed between each of the plurality of fins from FIG. 3B;

FIG. 3D illustrates a cross-sectional view depicting growth of a cladding layer on the structure of FIG. 3C; and

FIG. 3E illustrates a cross-sectional view depicting formation of a gate line on the structure of FIG. 3D.

FIG. 4 provides supporting data for benefits derived from multi-layer compliant substrates for non-planar devices, in accordance with an embodiment of the present invention.

FIG. 5A illustrates a cross-sectional view of a Ge or III-V channel semiconductor device having multi-layer compliance, in accordance with an embodiment of the present invention.

FIG. 5B illustrates a plan view taken along the a-a′ axis of the semiconductor device of FIG. 5A, in accordance with an embodiment of the present invention.

FIG. 6 illustrates a computing device in accordance with one implementation of the invention.

### DESCRIPTION OF THE EMBODIMENTS

Non-planar semiconductor devices having multi-layered compliant substrates and methods of fabricating such non-planar semiconductor devices are described. In the following description, numerous specific details are set forth, such as specific integration and material regimes, in order to provide a thorough understanding of embodiments of the present invention. It will be apparent to one skilled in the art that embodiments of the present invention may be practiced without these specific details. In other instances, well-known features, such as integrated circuit design layouts, are not described in detail in order to not unnecessarily obscure embodiments of the present invention. Furthermore, it is to be understood that the various embodiments shown in the Figures are illustrative representations and are not necessarily drawn to scale.

One potential way to integrate high mobility channel materials on silicon (Si) is with thin cladding layers on Si nanoscale templates. One or more embodiments described herein are directed to techniques for maximizing compliance and free surface relaxation in germanium (Ge) and III-V Transistors. One or more embodiments may be directed to one or more of cladding layers, compliant epitaxy, multi-layered compliance, germanium channel regions, III-V material channel regions, SiGe intermediate materials, transistor fabrication including metal oxide semiconductor (MOS) and complementary metal oxide semiconductor (CMOS) devices, compound semiconductor (III thru V) devices, finFET devices, tri-gate devices, nanoribbon devices, and nanowire devices.

To provide context, traditionally, the need for higher mobility channel materials has been described to enhance transistor performance, along with attempts to integrate such materials onto a silicon platform. Direct growth of such materials onto silicon (Si) suffers from high defect density arising from the large lattice mismatch of Ge (PMOS) and III-V (NMOS) materials which can exceed 8%. Though one approach is aspect ratio trapping (ART), another concept is that of growing the Ge or III-V film on a thin fin compliant substrate. Such an arrangement allows not only the film being deposited but also the thin Si-Fin (compliant) to accommodate some of the lattice mismatch and strain in the films which might then reduce the defects.

In accordance with an embodiment of the present invention, the concept of substrate compliance is extended to grow a strained film on silicon (such as SiGe) in order to form a new compliant template having a strain that allows for additional compliance to the final cladding layer of Ge or III-V material. The improved compliance stems from the fact that the SiGe, although lattice matched to the silicon substrate in the current flow direction, will by necessity have expanded in the vertical direction. The vertical stretch in SiGe lattice constant in turn enables the growth of the Ge or III-V cladding layer with less lattice mismatch in this direction and once again relieves part of the strain on the cladding layer. The compliance of such a SiGe layer is therefore enhanced over that of Silicon only and can reduce the tendency for formation of defects. Thus, one or more embodiments described herein provide approaches for improving epitaxial growth quality of compliant III-V and Ge channel transistor devices.

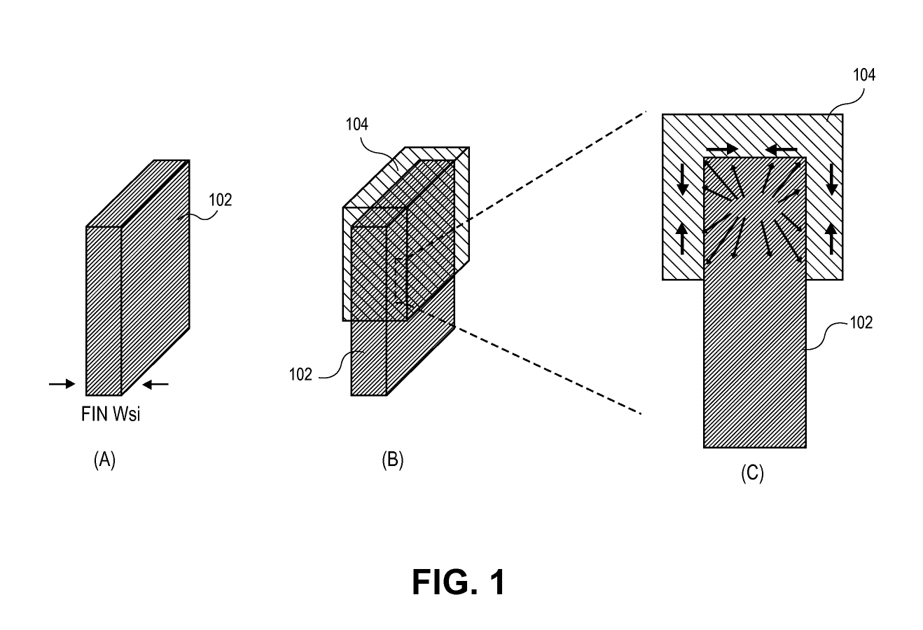

To demonstrate some of the concepts involved, FIG. 1 illustrates a silicon fin having a cladding layer formed thereon to provide a single layer compliant substrate. Referring to part (A) of FIG. 1, a silicon fin 102 has a width Wsi. Referring to part (B), a cladding layer 104 of Ge or III-V is formed on a portion of the fin 102 to provide a high mobility channel layer. The cladding layer 104 has a larger lattice constant than the silicon fin 102 and, as such, both layers are strained. Referring to part (C), a fin width cross-sectional view illustrates compliance of the fin 102 to the cladding layer 104 due to a narrow fin Wsi (free surface effect). As shown by the arrows within each layer, the thin silicon fin 102 and cladding layer 104 “comply” or stretch to accommodate epitaxial growth at free surfaces thereof.

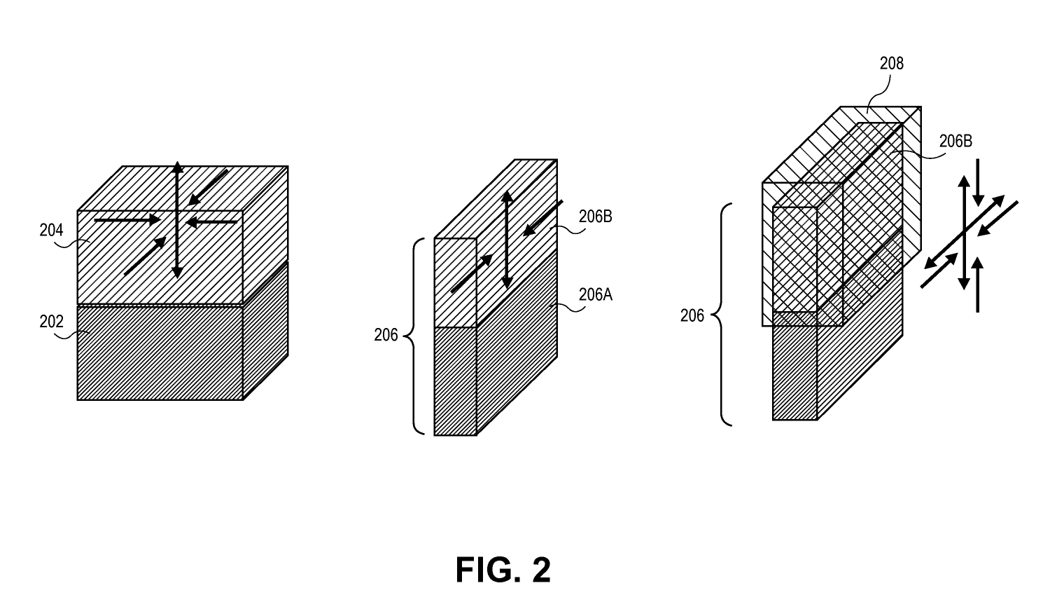

In accordance with an embodiment of the present invention, compliance of thin fin structures is enhanced by using a dual layer structure such as SiGe on Si for the starting substrate prior to deposition of a Ge or III-V cladding layer. As an example, FIG. 2 illustrates a silicon fin having a cladding layer formed thereon to provide a dual layer compliant substrate, in accordance with an embodiment of the present invention. Referring to part (A) of FIG. 2, a blanket silicon (Si) layer 202 has a biaxial strained SiGe film 204 formed thereon, e.g., SiGe with biaxial compressive strain in the XY direction along with additional vertical strain, as indicated by the arrows. Referring to part (B) of FIG. 2, the stack of part (A) is patterned to provide a fin 206 with a lower silicon portion 206A and an upper SiGe portion 206B. Patterning to form the fin 206 provides a uniaxial strained fin in the XY direction along with vertical strain, as indicated by the arrows. That is, the fin etch releases the biaxial strain layer to provide uniaxial strain. Referring to part (C) of FIG. 2, a cladding layer 208 is grown on the upper (SiGe) portion 206B of the fin 206. The resulting structure provides dual layer compliance, as indicated by the arrows. In particular, in one such embodiment, cladding layer 208 strain and lattice mismatch is reduced relative to the receiving fin due to incorporation of a strained intermediate layer (i.e., inclusion of the SiGe portion 206B). In an embodiment, then, multi-layer compliance is provided by forming a lower fin portion with a first lattice constant (L1), an upper fin portion with a second lattice constant (L2), and a cladding layer 208 (such as Ge or a III-V material) with a third lattice constant (L3), where L1<L2<L3.

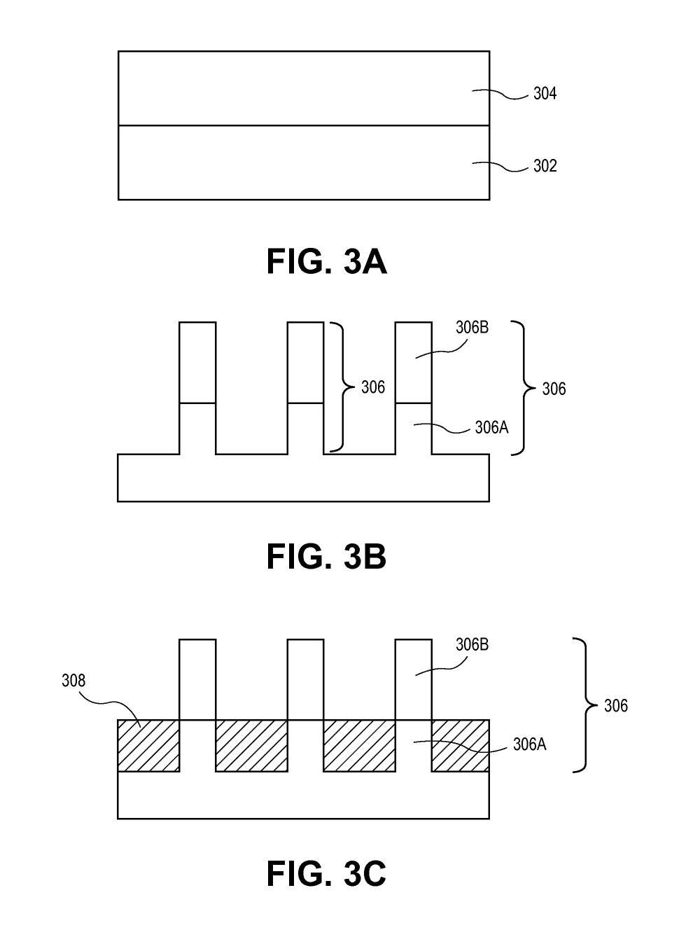

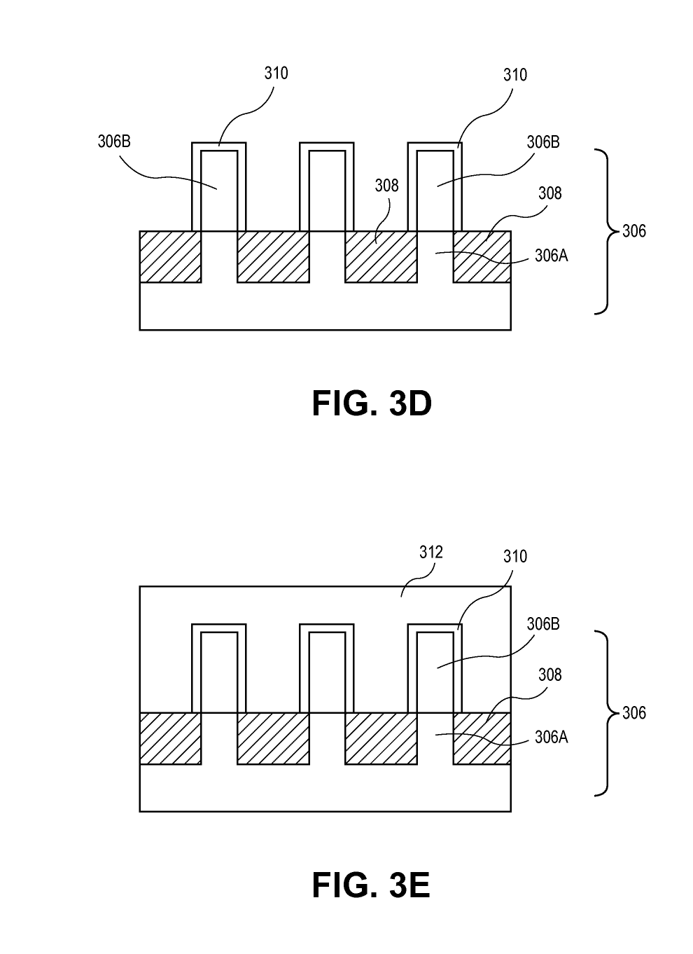

Thus, in contrast to the cladded trigate structure of FIG. 1, generally, one or more embodiments described herein provide an approach to fabricating multi-layer compliant substrates. In an example, FIGS. 3A-3E illustrate cross-sectional views of various operations in a method of fabricating a dual layer compliant substrate for a non-planar device, in accordance with an embodiment of the present invention.

Referring to FIG. 3A, a cross-sectional view depicts a semiconductor blanket stack having a second semiconductor layer 304 disposed on (e.g., by epitaxial growth) a first semiconductor layer 302. The first semiconductor layer may be part of a bulk substrate, such as a bulk single crystalline silicon substrate. In one embodiment, the second semiconductor layer is one having a lattice constant larger than the first semiconductor layer 302. For example, in a specific embodiment, the second epitaxial layer is composed of silicon germanium and is formed on an underlying silicon layer 302.

Referring to FIG. 3B, a cross-sectional view depicts a plurality of fins 306 as formed from the structure of FIG. 3A. Each of the plurality of fins 306 includes an upper fin portion 306B formed from the second semiconductor layer 304. Each of the plurality of fins 302 also includes a lower fin portion 306A formed from a portion of the first semiconductor layer 302. In an embodiment, in keeping with traditional bulk trigate manufacturing approaches, the fins 306 are formed into an underlying bulk substrate, e.g., where the first semiconductor layer 302 is the bulk substrate.

Referring to FIG. 3C, a cross-sectional view depicts isolation regions 308 formed between each of the plurality of fins 306 from FIG. 3B. The isolation regions 308 may be formed by first forming an isolation material (e.g., a layer of silicon dioxide) over the fins 306. The isolation material layer is then recessed to expose the upper portions of the fins 306. In one such embodiment, the resulting isolation regions 308 are formed to essentially or precisely the same level as the interface between the upper and lower portions of the fins 306 (e.g., at the same level as the interface between the first semiconductor material and the second semiconductor material), as is depicted in FIG. 3C. In another embodiment, the resulting isolation regions 308 are formed to a level slightly above the level of the interface between the upper and lower portions of the fin to ensure that only the second semiconductor material is exposed.

Referring to FIG. 3D, a cross-sectional view depicts growth of a cladding layer 310 on the structure of FIG. 3C. In particular, the cladding layer 310 is grown epitaxially on the protruding portions 306B of each fin 306. In one such embodiment, since the isolation regions 308 are at (or slightly above) the interface of the first and second semiconductor materials, the cladding layer growth is confined to the larger lattice constant material of fin upper portions 306B. In one embodiment, the cladding material is composed of a material having a lattice constant larger than the lattice constant of the upper fin portions 306B.

Referring to FIG. 3E, a cross-sectional view depicts formation of a gate line 312 on the structure of FIG. 3D. In particular, the gate line 312 is formed above/over the cladding layer 310 of each of the fins 306. The resulting device, then, provides a dual layer compliant substrate underneath the gate line 312. It is to be appreciated that the structure of FIG. 3E may subsequently be subjected to further processing, such as back end metallization, in order to incorporate the device into an integrated circuit such as a CMOS integrated circuit.

In an embodiment, the cladding layer 310 has a lower band gap yet larger lattice constant than the underlying upper fin portion 306B. In turn, the upper fin portion 306B has a larger lattice constant than the lower fin portion 306A (e.g., the Si portion of the fin). The cladding layer 310 may have a thickness suitable to propagate a substantial portion of a wave-function, e.g. suitable to inhibit a significant portion of the wave-function from entering the upper fin portion 306B and lower fin portion 306A. However, the cladding layer 310 may be sufficiently thin for compliance. In one embodiment, cladding layer 310 has a thickness approximately in the range of 10-50 Angstroms. The cladding layer 310 may be formed by a technique such as, but not limited to, chemical vapor deposition (CVD) or molecular beam epitaxy (MBE), or other like processes.

In a first embodiment, the cladding layer 310 is a germanium (Ge) cladding layer, such as a pure or essentially pure germanium cladding layer. As used throughout, the terms pure or essentially pure germanium may be used to describe a germanium material composed of a very substantial amount of, if not all, germanium. However, it is to be understood that, practically, 100% pure Ge may be difficult to form and, hence, could include a tiny percentage of Si. The Si may be included as an unavoidable impurity or component during deposition of Ge or may “contaminate” the Ge upon diffusion during post deposition processing. As such, embodiments described herein directed to a Ge cladding layer may include Ge materials that contain a relatively small amount, e.g., “impurity” level, non-Ge atoms or species, such as Si. Also, in alternative embodiments, SiGe is used, e.g., a SiₓGe_{y} layer, where 0<x<100, and 0<y<100, with a high % Ge content relative to silicon. In a second embodiment, the cladding layer 310 is a III-V material cladding layer. That is, in one embodiment, the cladding layer 310 is composed of groups III (e.g. boron, aluminum, gallium or indium) and V (e.g. nitrogen, phosphorous, arsenic or antimony) elements. In one embodiment, cladding layer 310 is composed of binary (e.g., GaAs) but can also be ternary or quarternary based III-V materials, etc.

In an embodiment, the lower fin portion 306BA is composed of silicon, and the upper fin portion 306B is composed of SiGe (SiₓGe_{y}, where 0<x<100, and 0<y<100). In one such embodiment, the SiGe has a low to intermediate % Ge content relative to silicon (e.g., 20-50% Ge with the remainder Si).

As mentioned above, in one embodiment, the illustration of FIG. 3C shows the process flow post fin etch and shallow trench isolation (STI) polish and recess following isolation oxide deposition. It is to be appreciated that artifacts that may have at one point remained from the fabrication of fins 06 have also been removed. For example, in one embodiment, a hardmask layer, such as a silicon nitride hardmask layer, and a pad oxide layer, such as a silicon dioxide layer, have been removed from the top surface of fins 306. In one embodiment, a corresponding bulk substrate and, hence, the lower portions of the fins 306A, are undoped or lightly doped at this stage. For example, in a particular embodiment, the bulk substrate and, hence, the lower portions of the fins 306A, have a concentration of less than approximately 1E17 atoms/cm³ of boron dopant impurity atoms. However, in other embodiments, well and/or retrograde implants have been, or will be, provided to the fins 306 and the underlying substrate. In one such example, such doping of the exposed fins 306 may lead to doping within the corresponding bulk substrate portion, where adjacent fins share a common doped region in the bulk substrate.

In an embodiment, referring again to FIG. 3C, the isolation region 308 is composed of silicon dioxide, such as is used in a shallow trench isolation fabrication process. The isolation region 308 may be formed by depositing a layer by a chemical vapor deposition (CVD) or other deposition process (e.g., ALD, PECVD, PVD, HDP assisted CVD, low temp CVD) and may be planarized by a chemical mechanical polishing (CMP) technique. The planarization may also removes any artifacts from fin patterning, such as a hardmask layer and/or pad oxide layer, as mentioned above. In an embodiment, recessing of a dielectric layer to provide isolation regions 308 defines the initial fin channel height. The recessing may be performed by a plasma, vapor or wet etch process. In one embodiment, a dry etch process selective to at least the upper portions 306B of fins 306 is used, the dry etch process based on a plasma generated from gases such as, but not limited to NF₃, CHF₃, C₄F₈, HBr and O₂ with typically pressures in the range of 30-100 mTorr and a plasma bias of 50-1000 Watts. It is to be appreciated that cladding layer 310 growth for compliant substrate fabrication increases the total fin height which is based on the extent of 306B protrusion in addition to top cladding layer thickness.

In an embodiment, gate line 312 patterning involves poly lithography to define a polysilicon gate (permanent or placeholder for a replacement gate process) by etch of an SiN hardmask and polysilicon subsequently. In one embodiment, a mask is formed on the hardmask, the mask composed of a topographic masking portion and an anti-reflective coating (ARC) layer. In a particular such embodiment, the topographic masking portion is a carbon hardmask (CHM) layer and the anti-reflective coating layer is a silicon ARC layer. The topographic masking portion and the ARC layer may be patterned with conventional lithography and etching process techniques. In one embodiment, the mask also includes and uppermost photo-resist layer, as is known in the art, and may be patterned by conventional lithography and development processes. In a particular embodiment, the portions of the photo-resist layer exposed to the light source are removed upon developing the photo-resist layer. Thus, patterned photo-resist layer is composed of a positive photo-resist material. In a specific embodiment, the photo-resist layer is composed of a positive photo-resist material such as, but not limited to, a 248 nm resist, a 193 nm resist, a 157 nm resist, an extreme ultra violet (EUV) resist, an e-beam imprint layer, or a phenolic resin matrix with a diazonaphthoquinone sensitizer. In another particular embodiment, the portions of the photo-resist layer exposed to the light source are retained upon developing the photo-resist layer. Thus, the photo-resist layer is composed of a negative photo-resist material. In a specific embodiment, the photo-resist layer is composed of a negative photo-resist material such as, but not limited to, consisting of poly-cis-isoprene or poly-vinyl-cinnamate.

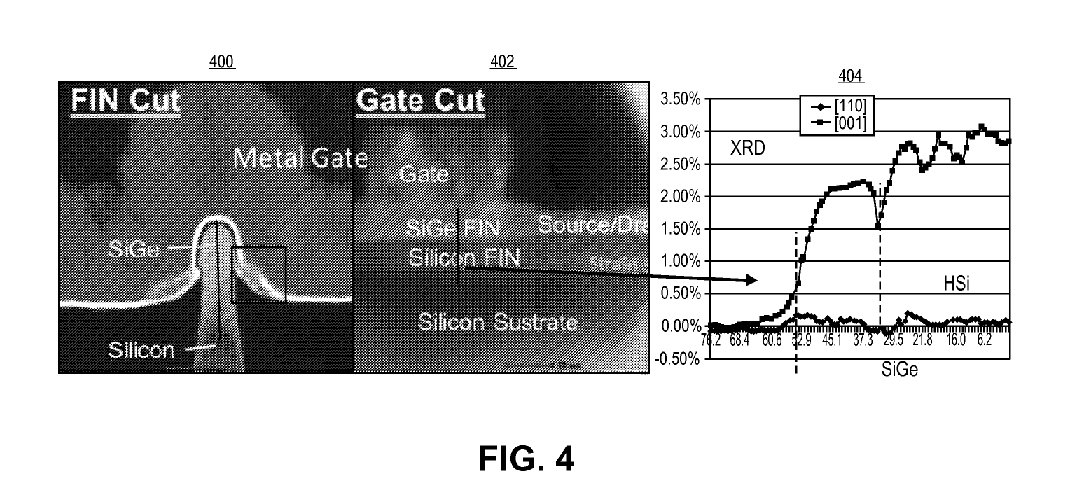

Pertinent to the structure shown in FIG. 3E, FIG. 4 provides supporting data for benefits derived from multi-layer compliant substrates for non-planar devices, in accordance with an embodiment of the present invention. Referring to FIG. 4, images 400 and 402 are cross-sectional TEM images showing a fin cut and a gate cut, respectively. Plot 404 shows X-ray diffraction (XRD) data indicating that SiGe on silicon achieves an approximately 3% vertical XRD shift in the SiGe lattice. The SiGe lattice can be used to lattice mismatch to a Ge or III-V material cladding layer, as described above.

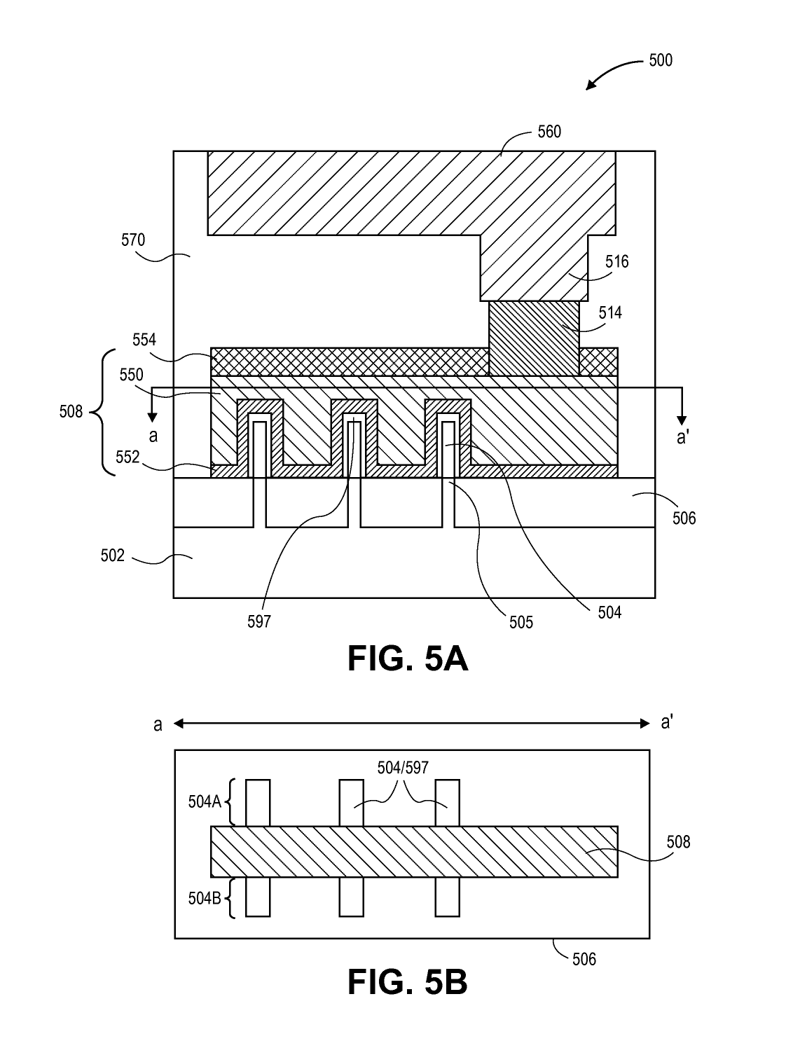

In general, referring again to FIGS. 2 and 3A-3E, in an embodiment, the approach described can be used for N-type (e.g., NMOS) or P-type (e.g., PMOS), or both, device fabrication. It is to be understood that the structures resulting from the above exemplary processing schemes, e.g., the structures from FIG. 3E, may be used in a same or similar form for subsequent processing operations to complete device fabrication, such as PMOS and NMOS device fabrication. As an example of a completed device, FIGS. 5A and 5B illustrate a cross-sectional view and a plan view (taken along the a-a′ axis of the cross-sectional view), respectively, of a Ge or III-V channel semiconductor devices having multi-layer compliance, in accordance with an embodiment of the present invention.

Referring to FIG. 5A, a semiconductor structure or device 500 includes a non-planar active region (e.g., a fin structure including protruding fin portion 504 and sub-fin region 505) formed from substrate 502, and within isolation region 506. In the case shown, three distinct fins are included in a single device. A channel region cladding layer 597 is formed to surround the protruding region 504 of each of the fins. In one such embodiment, the cladding region is composed of a semiconductor material having a lattice constant than the semiconductor material of the protruding region 504 of each of the fins, and the semiconductor material of the protruding region 504 of each of the fins has a lattice constant larger than the semiconductor material of the sub-fin region 505, as described above.

Referring again to FIG. 5A, a gate line 508 is disposed over the protruding portions 504 of the non-planar active region as well as over a portion of the isolation region 506. As shown, gate line 508 includes a gate electrode 550 and a gate dielectric layer 552. In one embodiment, gate line 508 may also include a dielectric cap layer 554. A gate contact 514, and overlying gate contact via 516 are also seen from this perspective, along with an overlying metal interconnect 560, all of which are disposed in inter-layer dielectric stacks or layers 570. Also seen from the perspective of FIG. 5A, the gate contact 514 is, in one embodiment, disposed over isolation region 506, but not over the non-planar active regions.

Referring to FIG. 5B, the gate line 508 is shown as disposed over the protruding fin portions 504. Source and drain regions 504A and 504B of the protruding fin portions 504 can be seen from this perspective. In one embodiment, the source and drain regions 504A and 504B include doped portions of original material of the protruding fin portions 504. In another embodiment, the material of the protruding fin portions 504 is removed and replaced with another semiconductor material, e.g., by epitaxial deposition. In that case, portions of the cladding layer 597 of the source and drain regions are also removed. In either case, the source and drain regions 504A and 504B may extend below the height of dielectric layer 506, i.e., into the sub-fin region 505. Alternatively, the source and drain regions 504A and 504B do not extend below the height of dielectric layer 506, and are either above or co-planar with the height of dielectric layer 506.

In an embodiment, the semiconductor structure or device 500 is a non-planar device such as, but not limited to, a fin-FET. However, a tri-gate or similar device may also be fabricated. In such an embodiment, a corresponding semiconducting channel region is composed of or is formed in a three-dimensional body. In one such embodiment, the gate electrode stacks of gate lines 508 surround at least a top surface and a pair of sidewalls of the three-dimensional body, as depicted in FIG. 5A.

Substrate 502 may be composed of a semiconductor material that can withstand a manufacturing process and in which charge can migrate. In an embodiment, substrate 502 is a bulk substrate composed of a crystalline silicon layer doped with a charge carrier, such as but not limited to phosphorus, arsenic, boron or a combination thereof, to form region 504. In one embodiment, the concentration of silicon atoms in bulk substrate 502 is greater than 99%. In another embodiment, bulk substrate 502 is composed of an epitaxial layer grown atop a distinct crystalline substrate, e.g. a silicon epitaxial layer grown atop a boron-doped bulk silicon mono-crystalline substrate. Alternatively, in place of a bulk substrate, a silicon-on-insulator (SOI) substrate may be used. In a particular embodiment, substrate 502 and, hence, subfin portions 505 of the fins, is composed of single crystalline silicon, the protruding portion of the fins 505 is composed of silicon germanium, and the cladding layer 597 is a Ge cladding layer or a III-V material cladding layer, as described above.

Isolation region 506 may be composed of a material suitable to ultimately electrically isolate, or contribute to the isolation of, portions of a permanent gate structure from an underlying bulk substrate or isolate active regions formed within an underlying bulk substrate, such as isolating fin active regions. For example, in one embodiment, the isolation region 506 is composed of a dielectric material such as, but not limited to, silicon dioxide, silicon oxy-nitride, silicon nitride, or carbon-doped silicon nitride.

Gate line 508 may be composed of a gate electrode stack which includes a gate dielectric layer 552 and a gate electrode layer 550. In an embodiment, the gate electrode of the gate electrode stack is composed of a metal gate and the gate dielectric layer is composed of a high-K material. For example, in one embodiment, the gate dielectric layer is composed of a material such as, but not limited to, hafnium oxide, hafnium oxy-nitride, hafnium silicate, lanthanum oxide, zirconium oxide, zirconium silicate, tantalum oxide, barium strontium titanate, barium titanate, strontium titanate, yttrium oxide, aluminum oxide, lead scandium tantalum oxide, lead zinc niobate, or a combination thereof. Furthermore, a portion of gate dielectric layer may include one or a few monolayers of native oxide formed from the top few layers of the cladding layer 597.

In one embodiment, the gate electrode is composed of a metal layer such as, but not limited to, metal nitrides, metal carbides, metal silicides, metal aluminides, hafnium, zirconium, titanium, tantalum, aluminum, ruthenium, palladium, platinum, cobalt, nickel or conductive metal oxides. In a specific embodiment, the gate electrode is composed of a non-workfunction-setting fill material formed above a metal workfunction-setting layer.

Spacers associated with the gate electrode stacks (not shown) may be composed of a material suitable to ultimately electrically isolate, or contribute to the isolation of, a permanent gate structure from adjacent conductive contacts, such as self-aligned contacts. For example, in one embodiment, the spacers are composed of a dielectric material such as, but not limited to, silicon dioxide, silicon oxy-nitride, silicon nitride, or carbon-doped silicon nitride.

Gate contact 514 and overlying gate contact via 516 may be composed of a conductive material. In an embodiment, one or more of the contacts or vias are composed of a metal species. The metal species may be a pure metal, such as tungsten, nickel, or cobalt, or may be an alloy such as a metal-metal alloy or a metal-semiconductor alloy (e.g., such as a silicide material).

In an embodiment (although not shown), providing structure 500 involves formation of a contact pattern which is essentially perfectly aligned to an existing gate pattern while eliminating the use of a lithographic step with exceedingly tight registration budget. In one such embodiment, this approach enables the use of intrinsically highly selective wet etching (e.g., versus conventionally implemented dry or plasma etching) to generate contact openings. In an embodiment, a contact pattern is formed by utilizing an existing gate pattern in combination with a contact plug lithography operation. In one such embodiment, the approach enables elimination of the need for an otherwise critical lithography operation to generate a contact pattern, as used in conventional approaches. In an embodiment, a trench contact grid is not separately patterned, but is rather formed between poly (gate) lines. For example, in one such embodiment, a trench contact grid is formed subsequent to gate grating patterning but prior to gate grating cuts.

Furthermore, the gate stack structure 508 may be fabricated by a replacement gate process. In such a scheme, dummy gate material such as polysilicon or silicon nitride pillar material, may be removed and replaced with permanent gate electrode material. In one such embodiment, a permanent gate dielectric layer is also formed in this process, as opposed to being carried through from earlier processing. In an embodiment, dummy gates are removed by a dry etch or wet etch process. In one embodiment, dummy gates are composed of polycrystalline silicon or amorphous silicon and are removed with a dry etch process including use of SF₆. In another embodiment, dummy gates are composed of polycrystalline silicon or amorphous silicon and are removed with a wet etch process including use of aqueous NH₄OH or tetramethylammonium hydroxide. In one embodiment, dummy gates are composed of silicon nitride and are removed with a wet etch including aqueous phosphoric acid. In an embodiment, replacement of a dummy gate dielectric layer with a permanent gate dielectric layer is additionally performed.

In an embodiment, one or more approaches described herein contemplate essentially a dummy and replacement gate process in combination with a dummy and replacement contact process to arrive at structure 500. In one such embodiment, the replacement contact process is performed after the replacement gate process to allow high temperature anneal of at least a portion of the permanent gate stack. For example, in a specific such embodiment, an anneal of at least a portion of the permanent gate structures, e.g., after a gate dielectric layer is formed, is performed at a temperature greater than approximately 600 degrees Celsius. The anneal is performed prior to formation of the permanent contacts.

Referring again to FIG. 5A, the arrangement of semiconductor structure or device 500 places the gate contact over isolation regions. Such an arrangement may be viewed as inefficient use of layout space. In another embodiment, however, a semiconductor device has contact structures that contact portions of a gate electrode formed over an active region. In general, prior to (e.g., in addition to) forming a gate contact structure (such as a via) over an active portion of a gate and in a same layer as a trench contact via, one or more embodiments of the present invention include first using a gate aligned trench contact process. Such a process may be implemented to form trench contact structures for semiconductor structure fabrication, e.g., for integrated circuit fabrication. In an embodiment, a trench contact pattern is formed as aligned to an existing gate pattern. By contrast, conventional approaches typically involve an additional lithography process with tight registration of a lithographic contact pattern to an existing gate pattern in combination with selective contact etches. For example, a conventional process may include patterning of a poly (gate) grid with separate patterning of contact features.

It is to be understood that not all aspects of the processes described above need be practiced to fall within the spirit and scope of embodiments of the present invention. For example, in one embodiment, dummy gates need not ever be formed prior to fabricating gate contacts over active portions of the gate stacks. The gate stacks described above may actually be permanent gate stacks as initially formed. Also, the processes described herein may be used to fabricate one or a plurality of semiconductor devices. The semiconductor devices may be transistors or like devices. For example, in an embodiment, the semiconductor devices are a metal-oxide semiconductor field effect transistors (MOS) transistors for logic or memory, or are bipolar transistors. Also, in an embodiment, the semiconductor devices have a three-dimensional architecture, such as a fin-FET device, a trigate device, or an independently accessed double gate device. One or more embodiments may be particularly useful for fabricating semiconductor devices at a 14 nanometer (14 nm) or smaller technology node.

In general, then, one or more embodiments described above enable reducing the lattice mismatch between a compliant substrate and the Ge or III-V cladding layers. A significant difference between such compliant fin substrate and single layer compliant substrates stems from the dual fin materials described above. Fabrication of fins having two different semiconductor materials stacked within each fin can be used to modulate the strain of a starting fin and the cladding layer deposited on the fin. Thus, novel high mobility materials such Ge or III-V may be introduced into the transistor channel, e.g., PMOS for the former and NMOS for the latter.

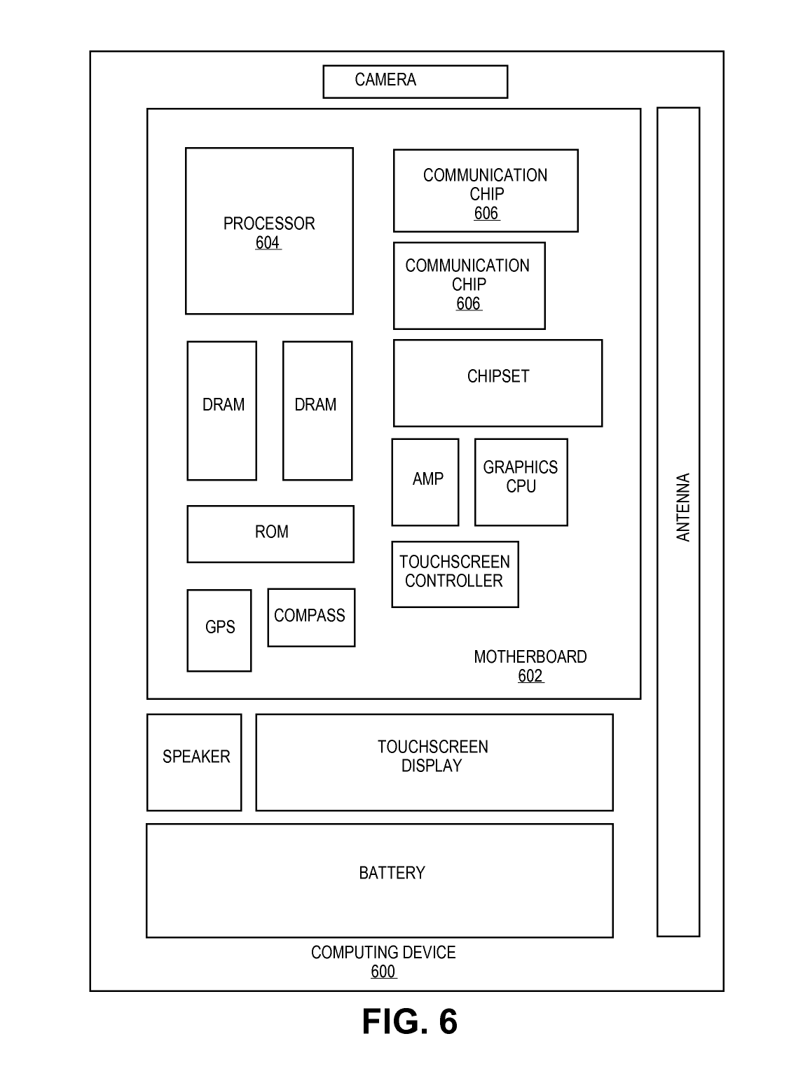

FIG. 6 illustrates a computing device 600 in accordance with one implementation of the invention. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processor 604.

Depending on its applications, computing device 600 may include other components that may or may not be physically and electrically coupled to the board 602. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. In some implementations of embodiments of the invention, the integrated circuit die of the processor includes one or more devices, such as Ge or III-V channel semiconductor devices having multi-layer compliant substrates built in accordance with implementations of the invention. The term “processor” may refer to any device or portion of a device that processes electronic data from registers and/or memory to transform that electronic data into other electronic data that may be stored in registers and/or memory.

The communication chip 606 also includes an integrated circuit die packaged within the communication chip 606. In accordance with another implementation of the invention, the integrated circuit die of the communication chip includes one or more devices, such as Ge or III-V channel semiconductor devices having multi-layer compliant substrates built in accordance with implementations of the invention.

In further implementations, another component housed within the computing device 600 may contain an integrated circuit die that includes one or more devices, such as Ge or III-V channel semiconductor devices having multi-layer compliant substrates built in accordance with implementations of embodiments of the invention.

In various embodiments, the computing device 600 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 600 may be any other electronic device that processes data.

Thus, embodiments of the present invention include non-planar semiconductor devices having multi-layered compliant substrates and methods of fabricating such non-planar semiconductor devices.

In an embodiment, a semiconductor device includes a semiconductor fin disposed above a semiconductor substrate. The semiconductor fin has a lower portion composed of a first semiconductor material with a first lattice constant (L1), and has an upper portion composed of a second semiconductor material with a second lattice constant (L2). A cladding layer is disposed on the upper portion, but not on the lower portion, of the semiconductor fin. The cladding layer is composed of a third semiconductor material with a third lattice constant (L3), wherein L3>L2>L1. A gate stack is disposed on a channel region of the cladding layer. Source/drain regions are disposed on either side of the channel region.

In one embodiment, the semiconductor fin and the cladding layer together provide a compliant substrate.

In one embodiment, the upper portion of the semiconductor fin protrudes above an isolation layer disposed adjacent to the lower portion of the semiconductor fin. Top surfaces of the isolation region and the lower portion of the semiconductor fin are at approximately the same level.

In one embodiment, the lower portion of the semiconductor fin is composed of silicon, the upper portion of the semiconductor fin is composed of silicon germanium, and the cladding layer region is composed of germanium.

In one embodiment, the semiconductor device is a PMOS device.

In one embodiment, the lower portion of the semiconductor fin is composed of silicon, the upper portion of the semiconductor fin is composed of silicon germanium, and the cladding layer region is composed of a III-V material.

In one embodiment, the semiconductor device is an NMOS device.

In one embodiment, the lower portion of the semiconductor fin is continuous with a bulk crystalline silicon substrate.

In one embodiment, the semiconductor device is a trigate transistor.

In an embodiment, a semiconductor device includes a semiconductor fin disposed above a semiconductor substrate. The semiconductor fin has a lower portion and an upper portion. A cladding layer is disposed on the upper portion, but not on the lower portion, of the semiconductor fin. The cladding layer and the semiconductor fin form a compliant substrate. The upper portion of the semiconductor fin relaxes stress between the lower portion of the semiconductor fin and the cladding layer. A gate stack is disposed on the cladding layer. Source/drain regions arte disposed on either side of the gate electrode.

In one embodiment, the upper portion of the semiconductor fin protrudes above an isolation layer disposed adjacent to the lower portion of the semiconductor fin. Top surfaces of the isolation region and the lower portion of the semiconductor fin are at approximately the same level.

In one embodiment, the lower portion of the semiconductor fin is composed of silicon, the upper portion of the semiconductor fin is composed of silicon germanium, and the cladding layer region is composed of germanium.

In one embodiment, the semiconductor device is a PMOS device.

In one embodiment, the lower portion of the semiconductor fin is composed of silicon, the upper portion of the semiconductor fin is composed of silicon germanium, and the cladding layer region is composed of a III-V material.

In one embodiment, the semiconductor device is an NMOS device.

In one embodiment, the lower portion of the semiconductor fin is continuous with a bulk crystalline silicon substrate.

In one embodiment, the semiconductor device is a trigate transistor.

In an embodiment, a method of fabricating a semiconductor device involves forming a second semiconductor material with a second lattice constant (L2) on a first semiconductor material with a first lattice constant (L1). The method also involves etching a semiconductor fin into the second semiconductor material and at least partially into the first semiconductor material, the semiconductor fin having a lower portion composed of the first semiconductor material and having an upper portion composed of the second semiconductor material. The method also involves forming an isolation layer adjacent to, and approximately level with, the lower portion of the semiconductor fin. The method also involves, subsequent to forming the isolation layer, forming a cladding layer on the upper portion of the semiconductor fin, the cladding layer composed of a third semiconductor material with a third lattice constant (L3), wherein L3>L2>L1. The method also involves forming a gate stack on a channel region of the cladding layer. The method also involves forming source/drain regions on either side of the channel region.

In one embodiment, forming the cladding layer on the upper portion of the semiconductor fin provides a compliant substrate.

In one embodiment, forming the cladding layer on the upper portion of the semiconductor fin involves epitaxially growing an essentially pure germanium layer.

In one embodiment, forming the cladding layer on the upper portion of the semiconductor fin involves epitaxially growing a III-V material layer.

In one embodiment, forming the second semiconductor material on the first semiconductor material involves epitaxially growing the second semiconductor material on a bulk crystalline substrate.

What is claimed is:

1. A semiconductor device, comprising:
a semiconductor fin disposed above a semiconductor substrate, the semiconductor fin having a lower portion comprising a first semiconductor material with a first lattice constant (L1) and having an upper portion comprising a second semiconductor material with a second lattice constant (L2);
a cladding layer disposed on the upper portion, but not on the lower portion, of the semiconductor fin, the cladding layer comprising a third semiconductor material with a third lattice constant (L3), wherein L3>L2>L1;
a gate stack disposed on a channel region of the cladding layer; and
source/drain regions disposed on either side of the channel region.

2. The semiconductor device of claim 1, wherein the semiconductor fin and the cladding layer together provide a compliant substrate.

3. The semiconductor device of claim 1, wherein the upper portion of the semiconductor fin protrudes above an isolation layer disposed adjacent to the lower portion of the semiconductor fin, wherein top surfaces of the isolation region and the lower portion of the semiconductor fin are at approximately the same level.

4. The semiconductor device of claim 1, wherein the lower portion of the semiconductor fin consists essentially of silicon, the upper portion of the semiconductor fin comprises silicon germanium, and the cladding layer region consists essentially of germanium.

5. The semiconductor device of claim 4, wherein the semiconductor device is a PMOS device.

6. The semiconductor device of claim 1, wherein the lower portion of the semiconductor fin consists essentially of silicon, the upper portion of the semiconductor fin comprises silicon germanium, and the cladding layer region consists essentially of a III-V material.

7. The semiconductor device of claim 6, wherein the semiconductor device is an NMOS device.

8. The semiconductor device of claim 1, wherein the lower portion of the semiconductor fin is continuous with a bulk crystalline silicon substrate.

9. The semiconductor device of claim 1, wherein the semiconductor device is a trigate transistor.

10. A semiconductor device, comprising:
a semiconductor fin disposed above a semiconductor substrate, the semiconductor fin having a lower portion and an upper portion;
a cladding layer disposed on the upper portion, but not on the lower portion, of the semiconductor fin, the cladding layer and the semiconductor fin forming a compliant substrate, wherein the upper portion of the semiconductor fin relaxes stress between the lower portion of the semiconductor fin and the cladding layer;
a gate stack disposed on a channel region of the cladding layer; and
source/drain regions disposed on either side of the channel region.

11. The semiconductor device of claim 10, wherein the upper portion of the semiconductor fin protrudes above an isolation layer disposed adjacent to the lower portion of the semiconductor fin, wherein top surfaces of the isolation region and the lower portion of the semiconductor fin are at approximately the same level.

12. The semiconductor device of claim 10, wherein the lower portion of the semiconductor fin consists essentially of silicon, the upper portion of the semiconductor fin comprises silicon germanium, and the cladding layer region consists essentially of germanium.

13. The semiconductor device of claim 12, wherein the semiconductor device is a PMOS device.

14. The semiconductor device of claim 10, wherein the lower portion of the semiconductor fin consists essentially of silicon, the upper portion of the semiconductor fin comprises silicon germanium, and the cladding layer region consists essentially of a III-V material.

15. The semiconductor device of claim 14, wherein the semiconductor device is an NMOS device.

16. The semiconductor device of claim 10, wherein the lower portion of the semiconductor fin is continuous with a bulk crystalline silicon substrate.

17. The semiconductor device of claim 10, wherein the semiconductor device is a trigate transistor.

18. A method of fabricating a semiconductor device, the method comprising:
forming a second semiconductor material with a second lattice constant (L2) on a first semiconductor material with a first lattice constant (L1);
etching a semiconductor fin into the second semiconductor material and at least partially into the first semiconductor material, the semiconductor fin having a lower portion comprising the first semiconductor material and having an upper portion comprising the second semiconductor material;
forming an isolation layer adjacent to, and approximately level with, the lower portion of the semiconductor fin;
subsequent to forming the isolation layer, forming a cladding layer on the upper portion of the semiconductor fin, the cladding layer comprising a third semiconductor material with a third lattice constant (L3), wherein L3>L2>L1;
forming a gate stack on a channel region of the cladding layer; and
forming source/drain regions on either side of the channel region.

19. The method of claim 18, wherein forming the cladding layer on the upper portion of the semiconductor fin provides a compliant substrate.

20. The method of claim 18, wherein forming the cladding layer on the upper portion of the semiconductor fin comprises epitaxially growing an essentially pure germanium layer.

21. The method of claim 18, wherein forming the cladding layer on the upper portion of the semiconductor fin comprises epitaxially growing a III-V material layer.

22. The method of claim 18, wherein forming the second semiconductor material on the first semiconductor material comprises epitaxially growing the second semiconductor material on a bulk crystalline substrate.
